(19) United States
(12) Patent Application Publication
(10) Pub. No.: US 2006/0192087 A1
(43) Pub. Date: Aug. 31, 2006

(54) Two-dimensional CMOS-based flat panel imaging sensor

(75) Inventors: Mario Kuszpet, Tel Aviv (IL); Shaul Dukeman, Eilat (IL); Horst F. Bruning, Livermore, CA (US); Neil T. Phipps, San Carlos, CA (US)

Correspondence Address: SQUIRE, SANDERS & DEMPSEY L.L.P, 600 HANSEN WAY, PALO ALTO, CA, 94304-1043, US

(73) Assignee: REAL TIME RADIOGRAPHY LTD., Jerusalem (IL)

(21) Appl. No.: 11/069,700

(22) Filed: Feb. 28, 2005

(51) Int. Cl. G01J 1/42; H01J 40/14

(52) U.S. Cl. 250/214 R; 250/208.2

(57) ABSTRACT

The present invention provides a large-area flat plate detector. The detector includes a conversion layer which converts incident electromagnetic radiation into electric charges. The detector has a first electrode in communication with the conversion layer and a second electrode formed as a plurality of pixels arranged in a matrix. The detector includes an array of CMOS tiles, each of the tiles comprised of a plurality of pixels and having four side abuttability. The tile array is configured so that each of the tiles is separated by a spacing equal to about one pixel length from every adjacent tile and internally configured to allow for a high readout rate. Each of the tile pixels is arranged in electrical communication with and mapped in one-to-one fashion with the pixels of the second electrode. The readout electronics is capable of reading out CMOS provided data at a rate of at least 30 fps.

### FIELD OF THE INVENTION

The present invention relates to a two-dimensional flat panel sensor for detecting and imaging electromagnetic radiation, typically, but without being limiting, X-ray radiation.

### BACKGROUND OF THE INVENTION

X-ray imaging has long been an accepted medical diagnostic tool. The oldest and still the most common form of X-ray imaging is conventional (still) radiography. In this modality, a burst of X-ray radiation produced by a high voltage vacuum tube irradiates a body region of clinical interest. The X-rays pass through that portion of the patient's body and a film is used to capture a still image. The exposed film is then chemically processed to create a visible image for diagnosis. Conventional radiography is commonly used to capture, as examples, thoracic, cervical, spinal, cranial, and abdominal images.

By the early 1960s X-ray technology had progressed to the point where dynamic imaging—moving rather than still pictures—became possible. This type of X-ray technology is commonly referred to as fluoroscopy. In fluoroscopic examinations, an image intensifier emits visible light when exposed to X-rays. The intensifier is coupled to a TV camera which replaces the film used in conventional radiography. Following the activation of an X-ray generator, “live” X-ray images of the patient are displayed on a TV monitor.

Dynamic fluoroscopic imaging is highly useful in situations where continuous images at 30 frames per second or higher are desirable, such as in cardiac catheterization, angiography and certain gastrointestinal studies. During fluoroscopic imaging, the patient as well as attending doctors and other health professionals, are continuously exposed to radiation, rather than receiving only short bursts of radiation as in conventional radiography.

Despite being widely used, image-intensifier-based fluoroscopic systems have major limitations. As an example, in the examination of lungs, a large area of about 40×40 cm must be imaged. This makes it necessary to significantly increase the size of the device, limiting accessibility to the patient. A further problem associated with image intensifiers is the degradation of image quality resulting from vignetting, pincushion distortions, etc inherent to this type of device.

Around 1990, researchers in X-ray physics recognized that the development of a flat panel X-ray detector replacing image intensifiers would be a major technological breakthrough in X-ray imaging. The same technology used to manufacture arrays of thin film transistors (TFT's) in liquid-crystal display screens was used to fabricate arrays of X-ray detector elements on a two-dimensional surface, which accelerated the development of practical devices. X-ray flat panel detectors have recently been put to practical use.

X-ray flat panel sensors and detectors can be classified into direct-conversion types and indirect-conversion types.

In direct-conversion sensors and detectors, a photoconductive substance that generates electric charges when X-rays or other kinds of radiation are projected thereon is used. X-rays are converted into electron-hole pairs by the photoconductive substance, and the converted electron-hole pairs are supplied as charges by an externally applied electric field to pixel electrodes arrayed in a matrix. The electron-hole pairs are accumulated in the pixel electrodes. The accumulated charges are sequentially read out as electrical signals to an integrating amplifier. This is effected via a signal line under the control of thin film transistor (TFT) switching elements where scanning lines are driven from an OFF to an ON potential. The readout signals are converted from analog to digital image data, which is outputted to a subsequent processing system.

Amorphous selenium, a material having high dark current resistance and reasonable photoconductivity when exposed to X-rays is the most commonly used type of material for direct-conversion X-ray detectors. Other materials, such as PbI₂, CdTe, GaAs and PbTe, may be used as well.

FIG. 1, to which reference is now made, shows a cut away view of a prior art direct-conversion flat panel image sensor 900 which includes: an active matrix substrate 902 which is substantially square and on which picture elements (pixels) 904 are arranged in a matrix; a substantially square semiconductor film 906, having a common center with, and formed on, the active matrix substrate 902; and a bias electrode 908 formed on substantially the entire surface of semiconductor film 906.

Reference is now made to FIG. 2 where the construction of a prior art single pixel in the sensor shown in FIG. 1 is illustrated. Each pixel 904 (FIG. 1) on the active matrix substrate 902 (FIG. 1) includes electrode wires arranged in an XY matrix including a scanning wire 910 and a signal (data) wire 912. Each pixel 904 also includes a thin film transistor (TFT) 914, and a charge storage element (CS) 916 formed with respect to the active matrix substrate 902 (FIG. 1). The semiconductor film 906 (FIG. 1) is made of a photoconductive substance.

In indirect-conversion sensors/detectors, incident X-rays are temporarily converted into light by a phosphor, usually Csl. The light is converted into electron-hole pairs by a photoelectric conversion film consisting of photodiode arrays with a thin-film transistor (TFT) readout switch at each picture element (pixel).

Two-dimensional image sensors are described in, for example, D. L. Lee, et al, A New Digital Detector for Projection Radiography, SPIE, 2432, pp 237-249, 1995 (published in May 1995); and Jacob Beutel, Harold L. Kundel and Richard L. Van Metter, Handbook of Medical Imaging, Volume 1, Physics and Psychophysics, SPIE Press, 2000, pp 225-276.

Coating materials used in currently available direct-conversion detectors/sensors produce a limited signal because the amount of charge generated as a consequence of the absorption of X-ray is limited. To increase the quantity of electric charges, it is necessary to form a photoconductive layer having a thickness of about 500 to 1500 micron. Formation of such a thick photoconductive layer takes a long time, and further, management of the fabrication process is complex. This results in extremely low productivity and high manufacturing costs.

Flat panel detectors of the indirect type present significant limitations as well. A major problem associated with indirect-conversion detectors is that the fluorescent light generated by the phosphor spreads in an isotropic manner and arrives at adjacent pixels. This leads to crosstalk effects and to the deterioration of the spatial resolution of the detected image. Furthermore, coating materials have a relatively low X-ray sensitivity. Put another way, the number of light photons generated per X-ray photon absorbed is relatively low. This severely limits the signal-to-noise ratio achievable with indirect-conversion systems.

A further limitation shared by detectors of both the indirect- and direct-conversion types is the use of TFT-based readout circuitries. TFT readout systems lack pixel amplification and, therefore, small signals have to be transported across the panel to reach off-device amplifiers. TFT-based readout circuitries also have the disadvantage that a whole line of pixels, rather than individual pixels, are addressed simultaneously. This severely limits readout speed and increases electronic noise. These inefficiencies mean that the noise associated with the electronic signal—readout noise—is greater than the signal produced by the fluoroscopic exposure. The result is degraded image quality which reduces the clinical usefulness of the image.

A further disadvantage of the TFT technology is that it requires a specialized fabrication process within a dedicated manufacturing facility, increasing both production and development costs.

### SUMMARY OF THE INVENTION

It is an object of the present invention to provide a large area flat panel detector for imaging having rapid readout capability of at least 30 frames per second (fps).

It is a further object of the present invention to provide a flat panel detector having a CMOS (complementary metal oxide semiconductor) tile array structure, each tile having four side abuttability.

Yet another object of the present invention is to provide CMOS tiles for use in arrays in flat panel detectors having rapid readout capability. Fabrication of the tiles for use in flat panel detectors is intended to be significantly less costly than fabrication of prior art TFT based detectors.

According to the present invention, there is provided a flat-panel detector comprising: a pair of electrodes, a conversion material positioned between the electrodes converting incident electromagnetic radiation into electric charges and a large-area, low electronic noise CMOS-based readout circuit, including integrated on-chip electronics.

With the CMOS-based readout circuitry of the present invention, each pixel is independently readout and the signal is immediately amplified. The through-hole technology and block architecture of the CMOS arrays described in the present invention provide off-chip localized signal paths and avoid extended pixel busses across the panel as used in TFT arrays.

The use of readout circuitry based on CMOS technology performs better and is less expensive than prior art TFT technology. CMOS circuitry takes advantage of the highly developed manufacturing infrastructure in the semiconductor industry by using the same fabrication processes used to make microprocessors and logic arrays.

The size of CMOS wafers used in the industry is relative small, 150 or 200 mm diameter. Accordingly, in the present invention, the “basic” CMOS readout unit, typically 10×10 cm, is made buttable on four sides. Several “basic” devices may be combined to form larger mosaics. Sixteen units positioned side-by-side can be used to produce a detector with an area of 40×40 cm. The information lost from missing pixels in the neighborhood of the butting lines can be easily reconstructed by using widely available interpolation methods.

The use of CMOS technology enables the addition of special features on a pixel-by-pixel basis, vastly improving the performance of the array. The noise levels that are achievable are significantly lower than that of TFT-based readout circuitry, and the CMOS circuits have larger dynamic ranges. In CMOS-based readout circuitries, typical noise levels below 500 electrons are achievable compared to at least 1500-2000 electrons in TFT-based readout systems. CMOS technology also makes it possible to integrate imaging, timing and readout functions all on the same device. The highly integrated architecture allows for the design of a “system on a chip”, which is less costly than an imager requiring large amounts of support electronics.

In one aspect of the present invention there is provided a large-area flat plate detector. The detector includes a conversion layer which includes one or more materials that convert incident electromagnetic radiation into electric charges, the conversion layer having a first and a second side; a first electrode in communication with the first side of the conversion layer for developing an electric field; and a second electrode formed as a plurality of pixels arranged in a matrix, the second electrode arranged in electrical communication with the second side of the conversion layer. The pixilated second electrode accumulates electric charge generated by the conversion layer under an electric field developed by applying a suitable voltage between the first and second electrodes. The detector also includes an array of CMOS tiles, each of the tiles comprised of a plurality of pixels and having four side abuttability. The array of tiles is configured so that each of the tiles is separated by a spacing equal to about one pixel length from every adjacent tile and internally configured to allow for a high readout rate. Each of the tile pixels is arranged in electrical communication with and mapped in one-to-one fashion with the pixels of the second electrode, each of the tile pixels thereby collecting the accumulated charge from its corresponding electrode pixel. The detector also includes one or more analog-to-digital converters for receiving from the pixels an amplified analog signal generated by the charges. The one or more analog-to-digital converters converts the signal to a digital signal. The detector contains a control system for controlling the readout of the signals generated by the charges and readout electronics arranged in electrical communication with the array of CMOS tiles and the one or more analog-to-digital converters and further arranged in communication with and controlled by the control system. The CMOS array is configured to output data at a rate of at least 30 fps.

In oner embodiment of the detector of the present invention, each of the CMOS tiles further includes one or more through-holes through which an amplified signal generated by the charges collected by the tile pixels is transferred and brought to the one or more analog-to-digital converters. Typically, each of the one or more through-holes is sized to replace no more than a single pixel in the CMOS tile.

In another embodiment of the detector, each of the CMOS tiles further includes one or more over-the-tile-edge connections positioned in the spacing between the tiles. A signal generated by the charges collected by the tile pixels is transferred through the connection to the one or more analog-to-digital converters.

In an embodiment of the detector of the present invention, the one or more analog-to-digital converters is positioned in each of the CMOS tiles. In this embodiment, each of the CMOS tiles may further include one or more through-holes through which the digital signal generated by the one or more analog-to-digital converters in the tile is transferred to the readout electronics.

In a further embodiment of the detector, the plurality of pixels in the array of tiles is internally configured into independent blocks, wherein the pixels in each of the blocks share common readout and control electronics thereby allowing high readout rates. In this embodiment, the independent blocks allow for processing data at a rate of up to about 120 fps.

In the detector, the conversion layer is a layer of photoconductive material for use in a detector of the direct-conversion type.

In yet another embodiment of the detector, the conversion layer includes material chosen from a group of photoconductive materials consisting of: HgI₂, CsI, PbI₂, NaI, CdS, Hg₂IN, HgBrN, Mn₃HgN, HgI₂BN, PbN₂, Pb(N₃)₂, GaAs, CdTe, CdZnTe, PbTe, Te and Se.

In an embodiment of the detector of the present invention, each of the pixels in the tiles includes one or more integrating capacitors for integrating charge arriving from the conversion layer, one or more storage capacitors for storing the integrated charge and one or more amplifiers.

In still another embodiment of the invention, the detector includes readout electronics which can process images at a rate of up to about 120 fps.

In a further embodiment of the detector, the detector has dimensions in excess of 35×35 cm in the x and y directions, this size achieved by combining an array of four side abuttable tiles.

In another aspect of the present invention there is provided a CMOS tile for use in CMOS array detectors. The CMOS tile comprises a plurality of pixels, each of the pixels includes one or more amplifiers, one or more integrating capacitors and one or more storage capacitors. These capacitors integrate and store electric charge respectively. The CMOS tile also includes one or more through-holes, the through-holes being sized to minimize the number of pixel defects in the tile resulting from including the one or more through-holes. The CMOS tile is internally configured to provide a set of parallel signals from the pixels via the one or more through-holes to external readout circuitry at a rate of not less than 30 fps. The signals are derived from the integrated and stored charges.

In an embodiment of the CMOS tile, the one or more through-holes is sized to replace no more than a single pixel in the CMOS tile.

In yet another embodiment of the CMOS tile, the plurality of pixels of the CMOS tile are internally configured into blocks, each block sharing common readout and control electronics allowing a readout rate of 30 fps or more.

In another aspect of the present invention there is provided an array of CMOS tiles for use in imaging. Each tile in the array is comprised of a plurality of pixels for receiving charge from a charge-providing source and each of the tiles has four side abuttability. Each of the tiles is spaced one pixel apart from its nearest neighbor tiles. The plurality of pixels of the tiles is internally configured into blocks, each block sharing common readout and control electronics allowing for a readout rate of 30 fps or more.

In an embodiment of the CMOS tile array, each of the CMOS tiles further includes one or more through-holes through which a signal generated by the charges received by the tile pixels is transferred and brought to one or more analog-to-digital converters. In this embodiment of the CMOS tile array, the one or more through-holes is sized to replace no more than a single pixel in the CMOS tile.

In still another embodiment of the CMOS tile array, each of the pixels comprises one or more amplifiers, one or more integrating capacitors and one or more storage capacitors, the capacitors for integrating and storing charge arriving from a charge-providing source.

In yet another embodiment of the CMOS tile array, each of the tiles further includes one or more over-the-tile-edge connections positioned in the spacings between the tiles. A signal generated by the charges collected by the tile pixels is transferred through the one or more connections to the one or more analog-to-digital converters.

In a further aspect of the present invention, there is provided a method for achieving high data readout rates in a two-dimensional imaging system. The method includes the steps of:
providing a detector of the system with an array of CMOS tiles, each tile including a plurality of pixels; and
configuring the plurality of pixels into groups, each group sharing common readout and control electronics thereby allowing data readout at a rate of 30 fps or more.

### BRIEF DESCRIPTION OF THE DRAWINGS

The invention is herein described, by way of example only, with reference to the accompanying drawings. With specific reference to the drawings in detail, it is stressed that the particulars shown are by way of example and for purposes of illustrative discussion of the preferred embodiments of the present invention only. The drawings are presented to provide what is believed to be the most useful and readily understood description of the principles and conceptual aspects of the invention. In this regard, no attempt is made to show structural details of the invention in more detail than is necessary for a fundamental understanding of the invention. The description of the invention below taken together with the drawings makes apparent to those skilled in the art how the several forms of the invention may be embodied in practice.

FIG. 1 is a cut away illustration of a prior art direct-conversion image sensor;

FIG. 2 is an enlarged view of a pixel in the prior art sensor shown in FIG. 1;

FIG. 3 illustrates a block diagram of an X-ray examination apparatus constructed according to the present invention;

FIG. 4 is a side view schematic representation of a two-dimensional image sensor based on a CMOS tile array, the sensor and CMOS tiles constructed according to the present invention;

FIG. 5 is a top view of a typical four-side abuttable CMOS array for use in image sensors constructed according to the present invention;

FIG. 6 is a schematic diagram of an embodiment of a pixel architecture usable with the pixels of the CMOS tiles shown in FIG. 4;

FIG. 7 is a timing diagram of the operation modes of the pixel architecture shown in FIG. 6;

FIGS. 8A-8C are schematic diagrams of various CMOS tile blocking approaches usable to speed up readout according to embodiments of the present invention;

FIG. 9 is a schematic diagram of a typical CMOS block structure constructed according to the present invention; and

FIG. 10 is a schematic diagram of the CMOS tile array structure constructed according to the present invention.

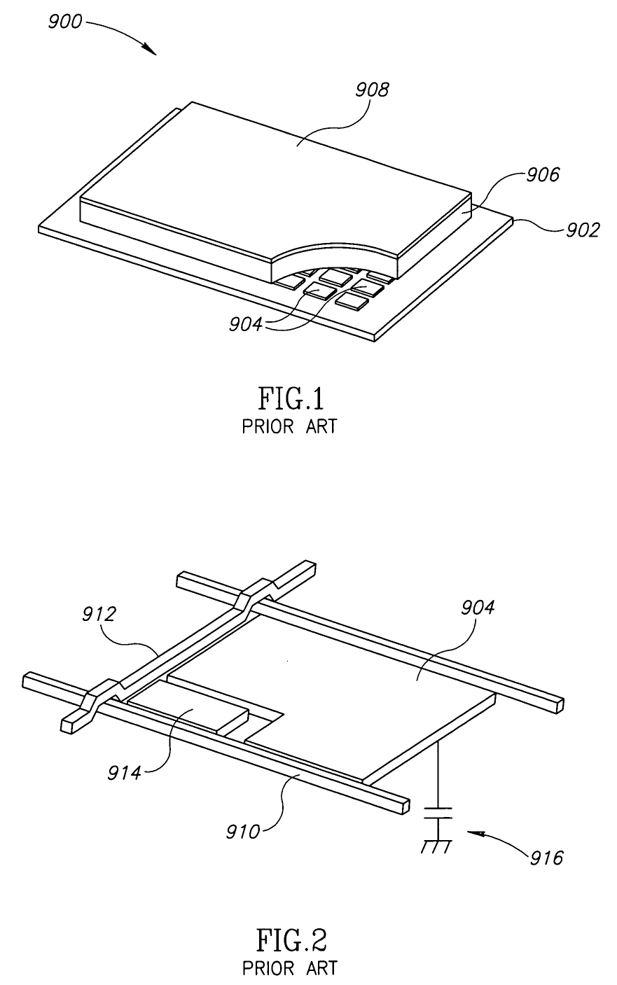

Similar elements in the Figures are numbered with similar reference numerals.

### DETAILED DESCRIPTION OF THE INVENTION

In what is described herein, “detector”, “sensor” and “imager” and words derived therefrom such as “sensing”, “detecting” and “imaging” will be used interchangeably. Unless the contrary is indicated, there will be no attempt to distinguish between these terms.

A flat-panel sensor of a direct-conversion type is herein proposed, wherein the sensor overcomes the problems inherent in both prior art indirect-conversion and direct-conversion sensors discussed above. The sensors discussed herein include high-speed CMOS-based readout circuitry. In the planar sensors of the present invention, incident X-rays are directly converted into electric charges which are then amplified and stored in each pixel of the sensor. The sensor incorporates a large-area CMOS tile array, each tile having four side abuttability and inter-tile distances of about a pixel. Four side abuttability as used herein is defined as a construction wherein tiles may be placed along the four borders of a given tile while maintaining a spacing between tiles of about one pixel. The CMOS-based array sensor can be used in high readout speed, dynamic imaging devices.

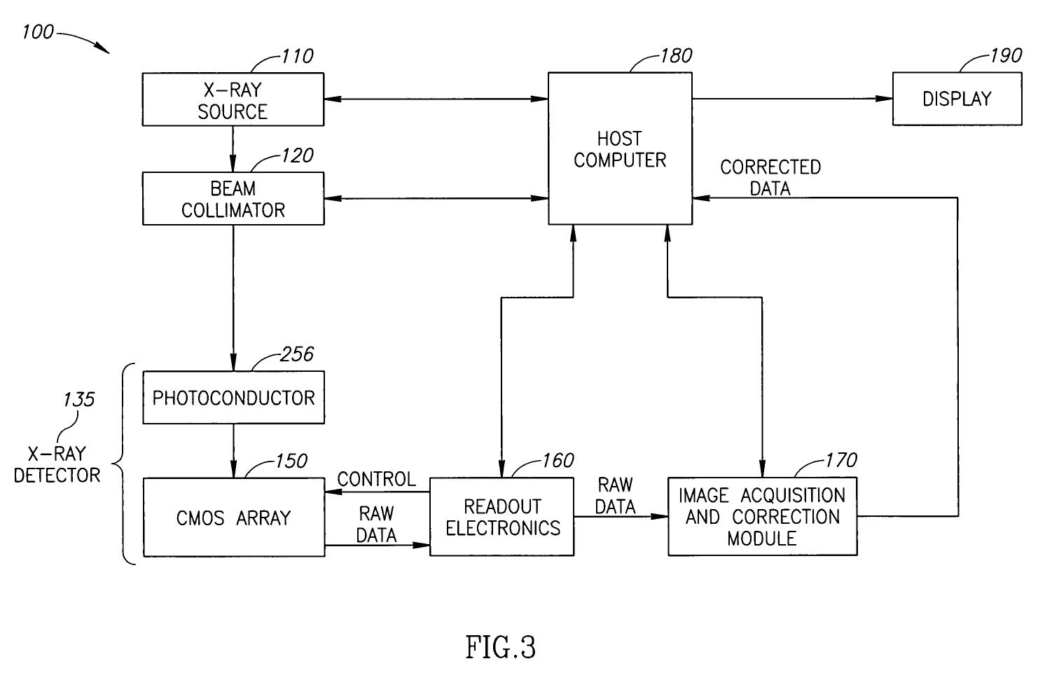

FIG. 3, to which reference is now made, schematically illustrates an X-ray examination apparatus in which a flat panel detector incorporating the sensors of the present invention may be used. The medical diagnostic imaging system 100 includes a plurality of subsystems. For the purposes of illustration only, the medical diagnostic imaging system 100 is described as an X-ray system but it should be understood that in other imaging systems, electromagnetic radiation in other wavelength ranges may be used.

The medical diagnostic imaging system 100 includes an X-ray source 110, a beam collimator 120 that is a device attached to the X-ray tube housing for the purpose of restricting the X-ray beam size, and an X-ray detector 135. Detector 135 includes a photoconductor material layer 256 in electrical communication with a CMOS array 150. The medical diagnostic imaging system 100 also includes a readout electronics acquisition module 160 and an image acquisition and correction module 170.

A patient is positioned in the medical diagnostic imaging system 100. In one exemplary system, the X-ray source 110 is positioned below the patient, while the X-ray detector 135 is positioned above the patient. In other systems, the X-ray detector 135 may be positioned below the patent with the X-ray source 110 being positioned above the patient.

X-rays produced by source 110 are attenuated to various degrees by the different types of tissue of the patient and transmitted to the photoconductor layer 256 of detector 135. Photoconductor layer 256 emits electrons in response to X-rays arriving from X-ray source 110 after passing through the patient.

Activation of the X-ray source 110 is controlled by a host computer 180, which also controls the aperture size of beam collimator 120. Collimator aperture size is inter alia a function of the size of the region selected for examination by the user.

As previously noted, photoconductor layer 256 generates electric charges that are readout by means of the CMOS array 150 and readout electronics 160. The CMOS array 150 is comprised of cells, also herein generally referred to as pixels, corresponding to pixels of the X-ray image. As will be described herein below in conjunction with FIG. 6, each cell/pixel in CMOS tile array 150, typically comprises an integrating capacitor and an amplifier. The cells/pixels are arranged in lines and columns and each cell/pixel is uniquely mapped to a pixel in the X-ray image. The readout electronics 160 reads out the individual cells/pixels in order to produce the desired digital X-ray image.

Upon completion of the firing of the X-ray source 110, or at pre-defined intervals in case the X-ray source 110 is operated in continuous mode, host computer 180 sends a signal to readout electronics 160 to start a CMOS-array readout cycle. Upon completion of the image readout cycle, data is outputted from the CMOS array 150 via readout electronics 160 and transferred to an image acquisition and correction module (IACM) 170. The latter module inter alia performs any required corrections to compensate for photoconductor layer 256 and CMOS array 150 imperfections. The corrected image is outputted to host computer 180 and displayed on monitor 190.

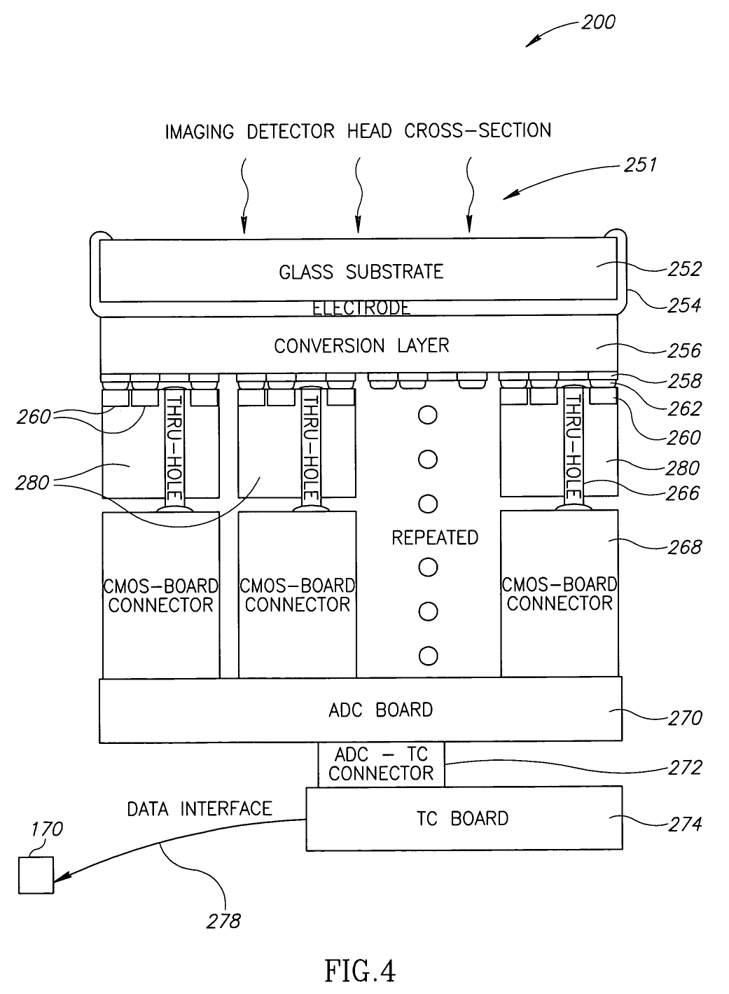

Reference is now made to FIG. 4 where a schematic side view representation of a two-dimensional image sensor 200 based on a CMOS tile 280 array is shown. The elements in FIG. 4 are not drawn to scale. The sensor 200 and CMOS tile 280 array is constructed in accordance with the present invention. In the present embodiment, the two-dimensional image sensor 200 will be explained by way of an exemplary two-dimensional X-ray image sensor. It should be understood that the described sensor 200 may be used with electromagnetic radiation other than X-ray radiation, if an appropriate conversion layer is used. The sensor 200 described in conjunction with FIG. 4 may be used as or in detector 135 and in readout electronics module 160 of FIG. 3.

As shown in FIG. 4, the two-dimensional image sensor 200 of the present embodiment has a basic configuration, which includes an upper electrode 254, a photoconductive conversion layer 256 and an active array composed of a plurality of CMOS tiles 280. CMOS-based sensor 200, like prior art TFT-based readout systems in direct-conversion detectors, are matrix-addressed arrays of integrating capacitors.

Very low noise levels, significantly lower than those of prior art TFT-based readout devices, can be attained with the CMOS tile array based sensor 200 shown in FIG. 4. This is due to the fact that each pixel has an amplifier incorporated within it. As a consequence, the sensor has excellent dynamic range. The dynamic range is usually defined as the ratio between the maximum signal and the noise floor. The maximum signal is about the same in TFT and CMOS-based circuitries. However, the noise floor is significantly lower in CMOS-based circuitries, thus significantly increasing the image dynamic range.

Each of the CMOS tiles 280 has four-side abuttablity which allows for constructing a sensor with a high density of tiles, each of the tiles functioning essentially independently. Electrode 254 is positioned on substrate 252, typically, but without being limiting, a glass substrate. Substrate 252 must be substantially transparent to the wavelength of the impinging radiation 251. For purposes of orientation and discussion only, the impinging radiation in FIG. 4 is said to be arriving from above and the glass substrate is to be considered the uppermost or topmost element of sensor 200. Similarly, transmission/control (TC) board element 274 is to be considered the bottommost element.

Since sensor 200 is an exemplary sensor, here being discussed in terms of X-ray detection and imaging, the conversion layer material of the embodiment is formed of inorganic materials sensitive to X-rays. In the preferred embodiment, mercuric iodide (HgI₂) is used, but other inorganic X-ray sensitive material, such as PbI₂, CsI, NaI, CdS, Hg₂IN, HgBrN, Mn₃HgN, HgI₂BN, PbN₂, Pb(N₃)₂, GaAs, CdTe, CdZnTe, PbTe, Te and Se may be used as well. These materials have a high absorption coefficient of X-rays and, thus, are used preferably. The material may be deposited using well-known physical vapor deposition techniques or by dispersing an X-ray detecting layer of photoconductor particles in a substantially radiation transparent charge transport/binder material. The latter will herein below be referred to as a particle in binder (PIB).

Mercuric iodide films, for example, directly convert X-rays into electrical signals with high efficiency. This is due to the material's high atomic number, high density, low energy requirement for generation of electron-hole pairs and high mobility-lifetime product (μT) of the majority charge carriers (electrons). It also exhibits low lag characteristics. Since blurring due to spreading of light, a limiting factor in indirect-conversion detectors, is eliminated, higher resolution is possible with such direct detectors than with detectors utilizing phosphor coatings. Typical sensitivities of mercuric iodide coatings are 3-5 times greater than those achievable using coating materials (e.g. CsI or Se) currently used in flat-panel detectors.

The high atomic number (Z value) of mercury makes HgI₂ an efficient material for absorbing X-rays when employing clinically useful X-ray exposure energies. In addition, the X-ray energy required to generate an electron-hole pair in mercuric iodide, as designated by the parameter W, is relatively low. The lower the W, the greater the number of charges generated by X-ray photons, and so the higher the X-ray sensitivity

The larger the mobility-lifetime (μT) product of the charge carriers, the greater the distance the electrical charges move in the detector. Greater distances result in higher sensitivity due to better charge collection. The high Z number, low W and high μT-product result in a very high signal, which can overcome all noise sources in fluoroscopic modes of operation. The ability to operate an HgI₂ imager at low bias voltages, imparts a further advantage.

Mercuric iodide is processed at relatively low temperatures. This allows for simple manufacturing techniques, a greater choice of substrate materials, and less danger of damaging expensive sensor readout circuitry during the coating process. The temperature stability of HgI₂ allows for operation, storage and transportation of these imagers under regular conditions and temperatures. Other materials, such as amorphous selenium, have storage and transportation problems that require them to be shipped and stored under special conditions. Even at non-extreme temperatures, amorphous selenium can irreversibly recrystallize with time causing it to cease to act as a detector.

The charge signal delivered by the photoconductive conversion layer 256 when exposed to X-rays 251 is propagated towards an array 150 (FIG. 3) of CMOS tiles 280 in FIG. 4. Each CMOS tile 280 in the array includes a plurality of pixels 260 and one or more through-holes 266, which lead the amplified signals generated in each of the CMOS tile's pixels to readout electronics below. Each CMOS pixel 260 is in electrical communication with a second electrode 258. Typically, this communication is enhanced by the use of electrically conductive glue 262.

The charge collected from conversion layer 256 is converted into a current (analog signal) within pixels 260 and delivered through a suitable sized through-hole 266 to a CMOS tile-analog-to-digital converter (ADC) connector 268 and from there to an ADC board 270. The current is there converted to a voltage by a current-to-voltage amplifier and subsequently digitized. It should be readily understood by one skilled in the art that the ADC functionality may be incorporated directly into the CMOS tile 280 and that a plurality of ADCs may be used, if needed.

Typically, and preferably, through-hole 266 should be fabricated so as to have as small a cross-sectional area as practicable. Typically, it will not be larger than about the size of a single pixel so that the number of “dead” pixels for which data interpolation will be needed will be minimized. If a pixel size of about 120 μ is used, through-holes having diameters of 60 μ are commercially achievable. Such through-hole sizes can be fabricated by, for example, Tru-Si Technologies Inc., Sunnyvale, Calif.

Through-holes, dimensioned as described above, allow for an inter-tile spacing of about a single pixel. Any other construction which allows for signal deliverance without interfering with an inter-tile spacing of about one pixel would also be acceptable.

Thus, for example, while the above embodiment makes use of one or more sized through-holes within a single CMOS tile, in other embodiments there may be a direct bond-wire connection from pixels 260 to connector 268 below. The connection would be formed and positioned so as to curl around the edge of tile 280, thereby reaching connector 268. The connection may be described as an over-the-tile-edge connection. The over-the-tile-edge connection is positioned solely within the inter-tile spacings.

The digital signal generated in ADC 270 is delivered through a connector 272 to a transmission/control (TC) board 274. The TC board 274 manipulates the digitized data from ADC 270 and sends it to the image acquisition and correction module 170 (FIG. 3) where correction of image imperfections is effected. Data is transferred to image acquisition and correction module 170 using standard data interface 278 construction methods, such as an interface cable constructed of fiber optics.

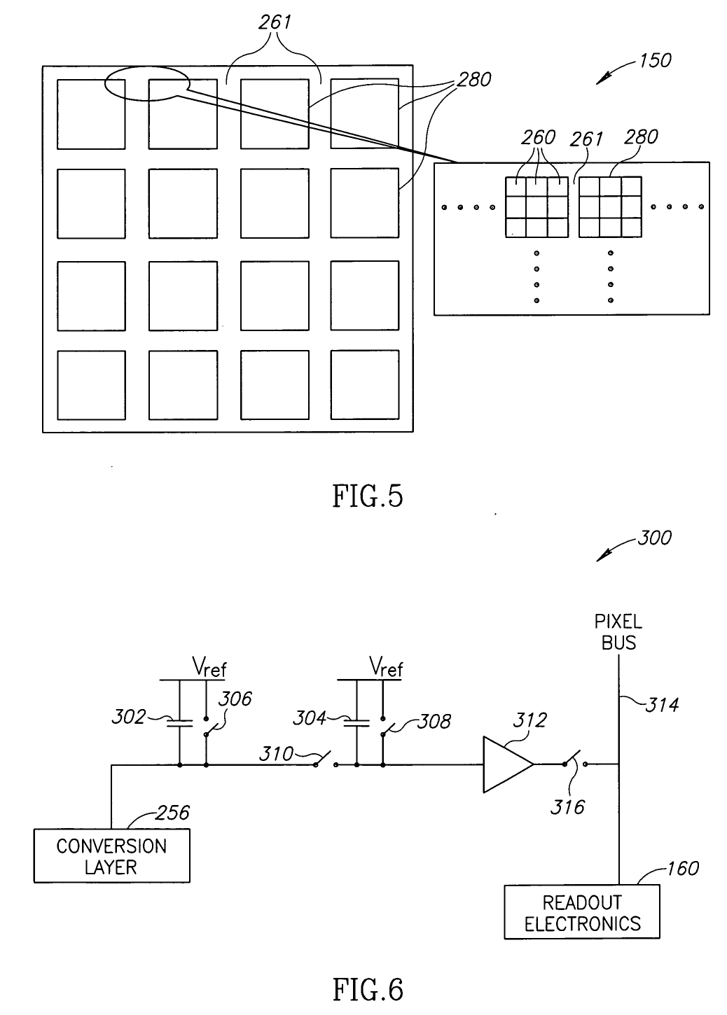

In the present invention, large-area CMOS based sensors 200 are manufactured so as to include an array having a large number of tiles 280. These tiles act as independent detectors and their four side abuttablity, as shown in FIG. 5, allows for a high density of tiles. FIG. 5, to which reference is now made shows an array 150 (FIG. 3) of 16 CMOS tiles 280, each tile having pixels 260 with a, typical but non-limiting, size of 120 μ. This architecture maximizes fabrication yield and avoids the considerable costs of larger systems. Sensors 200 composed of up to 25 CMOS tiles 280 may be manufactured easily.

The width of the gaps 261 between adjacent CMOS tiles 280 (FIGS. 4 and 5) should be no larger than about the size of a pixel in these tiles. This keeps all the sensor pixels 260 on a grid. The missing line/columns of pixels 260 in sensor 200 (FIG. 4) may be easily filled in by inserting data generated using suitable pixel correction algorithms known to persons skilled in the art. Typical algorithms which can be used include linear interpolation and/or cubic spline algorithms.

In sensor 200 of the embodiment illustrated in FIG. 4, all necessary interconnections between the CMOS tiles 280 and the data processing circuitry are made using through-wafer holing techniques. The number of interconnections needed is relatively small and, therefore, the number of non-functional pixels in the CMOS tile 280 array arising from the through-hole manufacturing process is small.

The sensor 200 with its CMOS tile 280 array shown in FIG. 4 allows for rapid parallel readout of at least one pixel from every tile in the array. The tiles effectively function independently. The more independent tiles there are, the more rapid the readout. There is, however, a practical limit to the number of tiles that will be used. Increasing the number of tiles increases the number of spacings between tile rows and columns interfering with the image produced.

Each pixel 260 in the CMOS tile 280 array has signal amplification capabilities, thus significantly enhancing the signal-to-noise ratio (SNR) achievable with sensors constructed according to the present invention. FIG. 6, to which reference is now made, shows an exemplary pixel architecture 300 that may be used for data readout.

The pixel circuit shown in FIG. 6 employs two capacitors 302 and 304, electrically connected via a transfer switch 310. Capacitors 302 and 304 integrate and store charge, respectively, with the charge being received from conversion layer 256 (FIG. 4).

The pixel circuit is operative in several different modes defined by the status of switches 310, 306, 308 and 316. These operative modes include:

1. Idle mode

2. Sampling mode

3. Readout mode

The sampling and readout modes may operate concurrently, that is the readout of frame n may occur concurrently while charge for frame n+1 is collected and sampled.

If the sensor's tile pixels are not actively being used for charge collection and transfer, that is if they are not being used in the sampling or readout modes, switches 306 and 308 are kept closed. This results in no charge being stored on integration capacitor 302 and storage capacitor 304 and the sensor is said to be in idle mode. Switches 310 and 316 are kept open when the sensor is in idle mode, and no pixels are selected for readout by host computer 180 (FIG. 3) with no charge transfer occurring.

When the sensor receives an appropriately timed trigger signal from host computer 180 (FIG. 3), the sensor switches to sampling mode where several sequential operations occur. Sampling mode functions include:
Charge collection—Switch 306 is opened. This allows charge from conversion layer 256 to accumulate on integration capacitor 302. Switch 308 may be closed or open at this stage, depending on whether or not readout of the previous sample is being performed. Shortly before charge integration is completed, reset switch 308 is opened.
Charge transfer—Upon completion of charge collection, switch 306 remains in the open state and switch 310 is closed. This connects integration capacitor 302 and storage capacitor 304 in parallel. Charge flows from integration capacitor 302 towards storage capacitor 304 until the potential in both capacitors is equalized. After an appropriate interval, switch 310 is again opened. Switch 306 is then closed, causing integration capacitor 302 to return to its zero stored charge condition. Another sampling operation will commence when the next trigger signal from host computer 180 (FIG. 3) is received.

The readout electronics addresses all the pixels sequentially through a readout operation after each sampling operation. The readout operation can be concurrent with the next charge collection and sampling operation. During readout, the charge stored on storage capacitor 304 at the completion of the charge transfer process is read out by closing switch 316. Once this switch is closed, the pixel amplifier 312 will conduct charge and a current proportional to the charge arriving from storage capacitor 304 flows to pixel bus 314.

After the current pixel is read out, the next pixel in the array is read out, and so on, until the entire pixel array has been outputted to bus 314. The signal is brought from bus 314 to readout electronics module 160 (FIG. 3).

The sensitivity of the pixel may be changed by judiciously selecting the capacitance values of the integration 302 and storage 304 capacitors, according to the expected range of the incoming charge. This may be controlled by host computer 180 (FIG. 3). A small integration capacitor capacitance value may be used in fluoroscopy applications where the X-ray exposure and expected signal levels are low. Larger capacitance values may be used in radiography applications where X-ray exposures are numerous and signal levels are high.

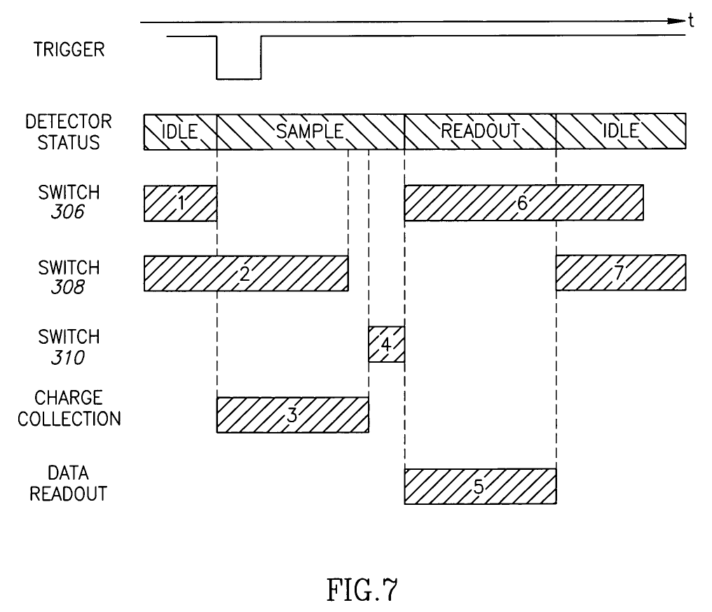

The high-level timing diagram of the operative modes described in conjunction with FIG. 6 is shown in FIG. 7 to which reference is now made. The x-axis in the Figure reflects increasing time, t. The relative sizes of the blocks numbered 1-7 in the Figure are not intended to reflect the relative sizes of the time intervals they represent.

When the sensor 200 (FIG. 4) is not actively being used for charge transfer, i.e. sampling, or readout, it remains in its idle mode with switches 306 and 308 closed (FIG. 6). This is indicated by blocks 1 and 2 respectively in FIG. 7.

The charge acquisition and transfer process is started when host computer 180 (FIG. 3) generates and sends a signal, labeled “trigger”, to readout electronics module 160 (FIG. 3). Upon detecting the trigger signal, the sensor goes into sampling mode. Readout electronics 160 opens switch 306 in all the pixels, placing the integration capacitors 302 (FIG. 6) of every pixel in their charge integration state. Switch 308 in all the pixels remains closed, keeping charge from being stored in the storage capacitors 304 (FIG. 6). Opening switch 306 in all the pixels is completed within a short time—typically 500 microseconds or less—after detection of the trigger signal. This 500 microseconds opening time is not shown in FIG. 7, since this time is negligible compared to the entire time required for sampling and/or readout.

The length of the charge collection period, shown as block 3 in the timing diagram of FIG. 7, is typically in the range of 33-150 milliseconds for average size patients, but may be up to 500 milliseconds for obese patients, and is set according to the imaging parameters selected by the host computer 180 (FIG. 3).

Shortly before the integration process is complete, readout electronics 160 simultaneously opens switch 308 in all the pixels. This prepares storage capacitor 304 in each pixel to receive charge accumulated in the integration capacitor 302 of that pixel. Opening switch 308 in all the pixels is completed before the charge collection period, block 3, is completed.

At the end of the charge collection period, block 3, readout electronics 160 closes switch 310 in every pixel, effectively transferring a part of the charge integrated by integration capacitor 302 to storage capacitor 304. This transfer process, shown as block 4 in the timing diagram of FIG. 7, is completed within a short time—typically 1 millisecond or less—after completion of charge collection, block 3.

The percentage of charge transferred to the storage capacitor 304 from integration capacitor 302 depends on the ratio between the capacitances of the two capacitors.

Once the charge transfer process is completed, the sampling process is completed and the sensor enters its readout mode. Readout electronics 160 opens switch 310 and closes switch 306 in every pixel. This effectively isolates integration capacitor 302 from storage capacitor 304, and causes no charge to be stored in integration capacitor 302. This is shown as block 6 in FIG. 7. Switch 306 will remain closed as long as host computer 180 does not generate a further trigger pulse.

Following the opening of transfer switch 310, readout electronics 160 starts the readout process of the charge stored in storage capacitor 304 in each of the pixels. In order to read out a specific pixel, the readout electronics closes pixel select switch 316 (FIG. 6). Once this switch is closed, pixel amplifier 312 (FIG. 6) will start to conduct and a current proportional to the charge will flow onto pixel bus 314 (FIG. 6). After a pixel is read out, switch 316 is opened and the next pixel in the array is read out, and so on, until every pixel in the entire pixel array has been outputted.

The readout process is shown as block 5 in FIG. 7. The raw data received from CMOS tile 280 based array (FIG. 4) is then transferred to readout electronics module 160 via pixel bus 314.

Once the readout process of the entire pixel array has been completed, the readout electronics closes switch 308 in all the pixels, thus causing zero charge to be stored in the storage capacitor 304. This is shown as block 7 in FIG. 7. The sensor returns to idle mode, awaiting another trigger pulse.

It should be noted that blocks 1, 2, 3, 4, 6, and 7 of FIG. 7 all take place simultaneously for all pixels. During the readout process (block 5), the pixels are sequentially addressed.

It should also be noted that in the circuitry shown in FIG. 6 a new charge collection period might be initiated by the host computer 180 (FIG. 3) in parallel to the readout process of the previous image. To do so, the host computer 180 will generate a new trigger pulse shortly after the completion of the charge collection process (block 3 in FIG. 7) of the previous image, with attendant closure of switch 306 (FIG. 6) in all the pixels of the array.

It should be evident to one skilled in the art that the pixel architecture discussed in conjunction with FIG. 6 above is intended to be exemplary only. Other architectures using at least one amplifier and a plurality of capacitors may also be used. Similarly, the timing diagram in FIG. 7 and the time durations discussed therewith are exemplary only; other timing diagrams and time durations are also possible depending on the pixel architecture.

In order to further increase the array readout speed over and above using a large array of independently-read CMOS tiles, each CMOS tile is divided into blocks. A block is herein deemed to be a collection of pixels on a CMOS tile that acts as an autonomous unit during data readout. Each block has analog outputs that serially provide the data readout for all the block's pixels to the one or more ADCs 270 (FIG. 4).

It should be noted that in what has been described and claimed herein, “blocks” and “groups” may be used interchangeably without any intent at distinguishing between them. This is also true of derivative wording such as “blocking” and “grouping”.

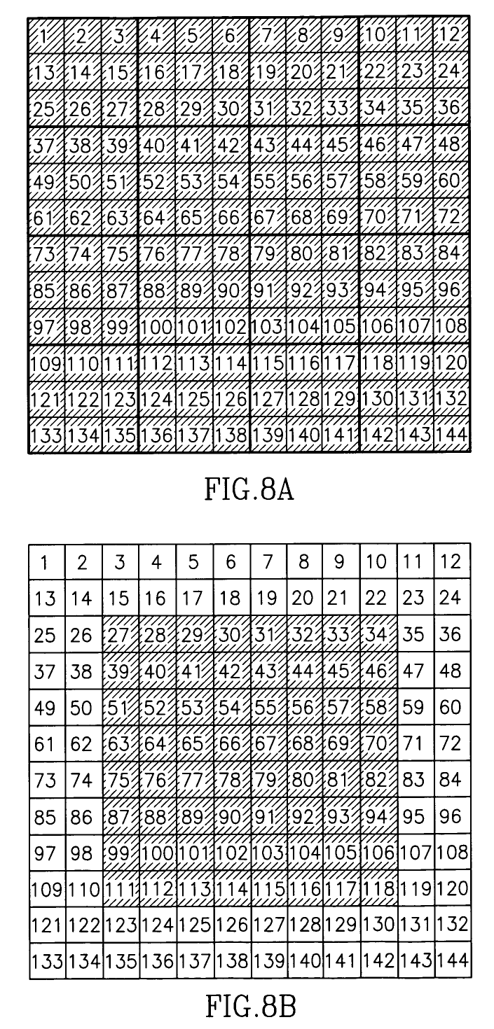

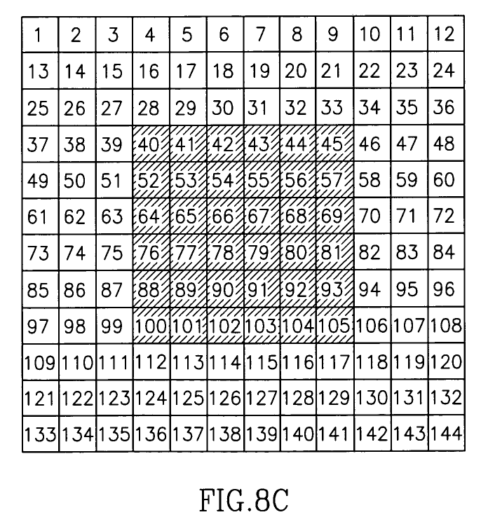

As an example, FIGS. 8A-8C, to which reference is now made, show various possible “blocking” layouts of a detector built according to the concepts outlined above.

In FIG. 8A, the detector has 16 CMOS tiles (surrounded by thick black lines in the Figure), each tile consisting of 9 blocks. In this example, each block is constructed so as to contain 256 pixels, each pixel having dimensions of 120×120 μ. Each block will therefore have dimensions of 3.072×3.072 cm. Each CMOS tile will then have a size of 9.216×9.216 cm, easily achievable using standard 150 mm wafers. The total detector size will then be 36.86×36.86 cm.

Due to the modular design used, larger or smaller detector sizes may be easily achieved employing a different number of tiles and/or a different number of blocks per tile. As an example, a 5×5 matrix array with the same block configuration as shown in FIG. 8A will lead to a total detector size of about 46×46 cm, while a 3×3 matrix array will generate a detector with a total size of 27.6×27.6 cm.

The subdivision of each CMOS tile 280 into blocks significantly alleviates the pixel's bandwidth requirements. For an acquisition rate of 30 frames per second (fps), the rate used in current medical fluoroscopy, using a matrix of 3,072×3,072 pixels, and assuming a slight time overlap between images, the approximate equivalent pixel clock rate is about 32 milliseconds/3,072×3,072 pixels=3.39 nanoseconds/pixel. However, since 144 pixels (i.e. the full detector is divided into 12×12 blocks) are read out simultaneously, each block is effectively interrogated every 488 nanoseconds, which is an equivalent bandwidth of roughly 2 MHz.

A further advantage of the block subdivision is that it enables outputting the data of a detector sub-region at higher acquisition rates. FIG. 8B and FIG. 8C show the area that may be outputted at frame rates of 60 fps (2,048×2,048 pixel detector, 8×8 blocks) and 120 fps (1,536×1,536 pixel detector, 6×6 blocks) respectively, without increasing the bandwidth requirements of the system.

As noted above, data from the CMOS tiles 280 (FIG. 4) is transferred to one or more ADCs 270 (FIG. 4) where the data is digitized. Since the bandwidth requirements (about 300 MHz for a 3,072×3,072 pixel detector run at 30 frames per second) is very high, several analog-to-digital converters (ADC) may, and usually will, be hooked up in parallel using known multiplexing techniques. ADCs typically run at up to 100 MHz, and, therefore, only a relatively small number of ADCs are required to properly digitize the incoming signal.

The blocking technique for increasing readout speed requires special hardware configurations. The tile is designed so that all the pixels in a block are connected to a single pixel bus.

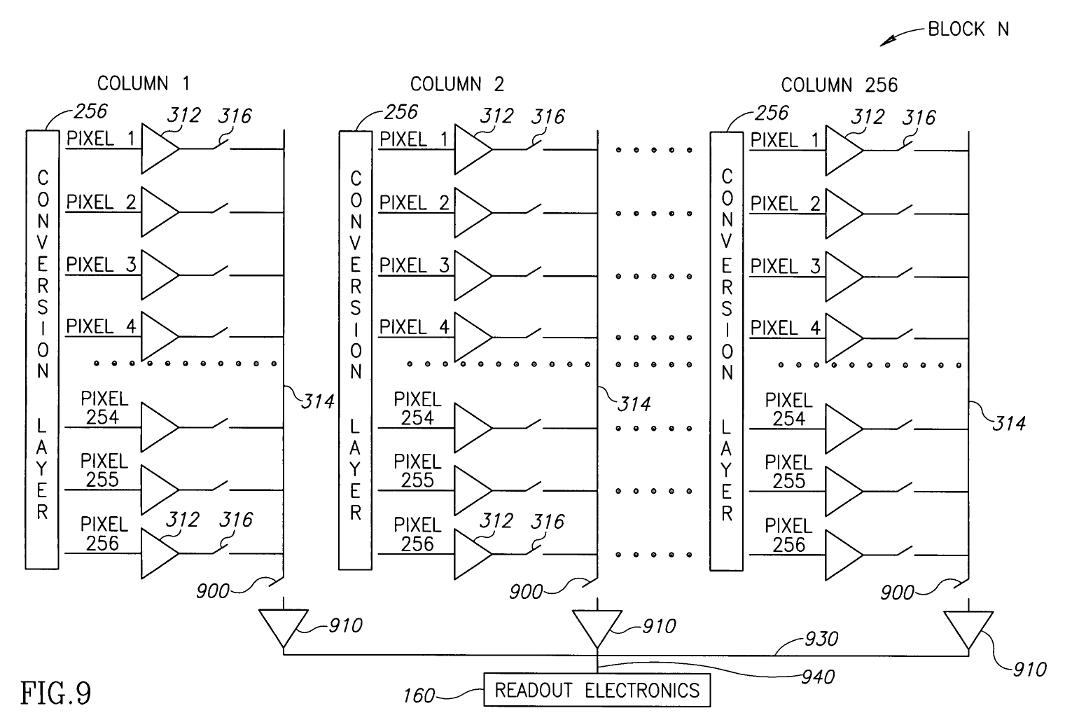

A schematic illustration of the block configuration of block N is shown in FIG. 9, to which reference is now made. FIG. 9 represents a CMOS-block configured to contain 65,536 pixels, arranged as 256 rows and 256 columns. It is readily understood that the number of rows and columns and the number of pixels discussed here are to be considered as illustrative only and they are not intended to be limiting.

A photoconductive conversion layer 256 from a sensor is positioned adjacent to a plurality of CMOS tile pixels. Most of the pixel architecture is not shown in FIG. 9. What are shown of each pixel's architecture are amplifier 312, readout switch 316, and pixel bus 314. The pixel buses 314 of each column are led through switch 900 and current amplifier 910 to a collection line 930 which in turn leads an outputted signal 940 to readout electronics module 160. For simplicity, the additional electronics elements present in sensor 200 of FIG. 4, such as connectors 272, 268 TC board 274 and ADCs 270, are not shown.

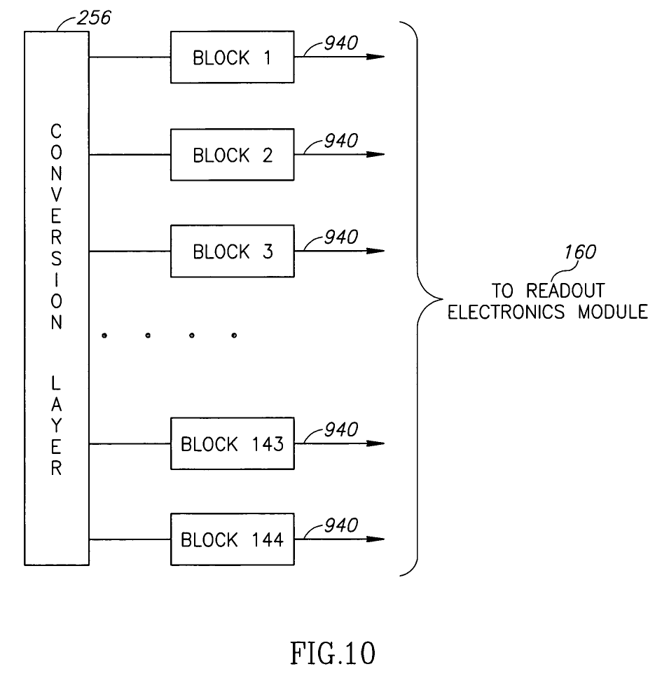

A schematic illustration of the CMOS tile array configuration is shown in FIG. 10, to which reference is now made. FIG. 10 represents a CMOS-array configured to contain 144 blocks, each having 65,536 pixels as described in FIG. 9. The signal output 940 of each individual block is transferred to readout electronics module 160, where it is converted by one or more analog-to digital converters into a voltage and digitized. This digitization process is performed using multiplexing techniques known to those skilled in the art.

As noted above, the exemplary blocking arrangements discussed above can be modified to enable data acquisition of up to a rate of about 120 fps. This is a rate unattainable with conventional prior art TFT-based readout circuits.

The present invention provides a sensor/detector/imager substantially as described above and as illustrated in the Figures. It is also contemplated that the present invention provides a construction for a CMOS tile and an array of CMOS tiles substantially as described above and as illustrated in the Figures. Readout of the blocks in the array occurs in parallel, but the pixels of a given block are readout serially.

The present invention also provides a method for achieving high data readout rates in a two-dimensional imaging system. The method includes the steps of:
providing a detector of the system with an array of CMOS tiles, each tile including a plurality of pixels; and
configuring the plurality of pixels into groups, each group sharing common readout and control electronics thereby to allow data readout at a rate of 30 fps or more.

It is appreciated that certain features of the invention, which are described, for clarity, in the context of separate embodiments, may also be provided in combination in a single embodiment. Conversely, various features of the invention, which are, for brevity, described in the context of a single embodiment, may also be provided separately or in any suitable sub-combination.

Although the invention has been described in the text and illustrated in the Figures in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. Further, the order of the steps of the method outlined herein is not intended to impose a particular order of the steps. It is to be understood that the phraseology and terminology employed herein is for the purpose of description and should not be regarded as limiting.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

What is claimed is:

1. A large-area flat plate detector, which comprises:
a conversion layer which includes at least one material that converts incident electromagnetic radiation into electric charges, said conversion layer having a first and a second side;
a first electrode in communication with said first side of said conversion layer;
a second electrode formed as a plurality of pixels arranged in a matrix, said electrode arranged in electrical communication with said second side of said conversion layer, so as to accumulate electric charge generated by said layer under an electric field developed by applying a suitable voltage between said first and second electrodes;
an array of CMOS tiles, each of said tiles comprised of a plurality of pixels and having four side abuttability, said array of tiles configured so that each of said tiles is separated by a spacing equal to about one pixel length from every adjacent tile and internally configured to allow for a high readout rate, each of said tile pixels arranged in electrical communication with and mapped in one-to-one fashion with said pixels of said second electrode, each of said tile pixels thereby collecting the accumulated charge from its corresponding electrode pixel;
at least one analog-to-digital converter for receiving from said pixels an amplified analog signal generated by said charges, said at least one analog-to-digital converter converting the signal to a digital signal;
a control system for controlling the readout of the signals generated by said charges; and
readout electronics arranged in electrical communication with said array of CMOS tiles and said at least one analog-to-digital converter and further arranged in communication with and controlled by said control system, said CMOS array configured to output data at a rate of at least 30 fps.

2. A large area flat plate detector according to claim 1 wherein each of said CMOS tiles further includes at least one through-hole whereby an amplified signal generated by the charges collected by said tile pixels is transferred through said through-hole and brought to said at least one analog-to-digital converter.

3. A large area flat plate detector according to claim 2 wherein each of said at least one through-hole is sized to replace no more than a single pixel in said CMOS tile.

4. A large area flat plate detector according to claim 1 wherein each of said CMOS tiles further includes at least one over-the-tile-edge connection positioned in said spacing between said tiles, whereby a signal generated by the charges collected by said tile pixels is transferred through said connection to said at least one analog-to-digital converter.

5. A large area flat plate detector according to claim 1 wherein said at least one analog-to-digital converter is positioned in each of said CMOS tiles.

6. A large area flat plate detector according to claim 5 wherein each of said CMOS tiles further includes at least one through-hole whereby the digital signal generated by said at least one analog-to-digital converter in said tile is transferred through said through-hole to said readout electronics.

7. A large flat plate detector according to claim 1 wherein said plurality of pixels in said array of tiles is internally configured into independent blocks, wherein said pixels in each of said blocks share common readout and control electronics thereby to allow high readout rates.

8. A large area flat plate detector according to claim 7 wherein said independent blocks allow for processing data at a rate of up to about 120 fps.

9. A large area flat plate detector according to claim 1 wherein said conversion layer is a layer of photoconductive material for use in a detector of the direct-conversion type.

10. A large area flat plate detector according to claim 1 wherein said conversion layer includes material chosen from a group of photoconductive materials consisting of: HgI₂, CsI, PbI₂, NaI, CdS, Hg₂IN, HgBrN, Mn₃HgN, HgI₂BN, PbN₂, Pb(N₃)₂, GaAs, CdTe, CdZnTe, PbTe, Te and Se.

11. A large area flat plate detector according to claim 1, wherein said at least one material in said conversion layer is HgI₂.

12. A large area flat plate detector according to claim 1, wherein each of said pixels in said tiles comprises at least one integrating capacitor for integrating charge arriving from said conversion layer, at least one storage capacitor for storing the integrated charge and at least one amplifier.

13. A large area flat plate detector according to claim 1, wherein said detector has dimensions in excess of 35×35 cm in the x and y directions, this size achieved by combining four side abuttable tiles.

14. A CMOS tile for use in CMOS array detectors, said CMOS tile comprising:
a plurality of pixels, each of said pixels comprising at least one amplifier, at least one integrating capacitor and at least one storage capacitor for integrating and storing electric charge; and
at least one through-hole, said through-hole being sized to minimize the number of pixel defects in said tile resulting from including said at least one through-hole in said tile,
said tile being internally configured to provide a set of parallel signals from said pixels via said at least one through-hole to external readout circuitry at a rate of not less than 30 fps, the signals being derived from the integrated and stored charges.

15. A CMOS tile according to claim 14 wherein said at least one through-hole is sized to replace no more than a single pixel in the CMOS tile.

16. A CMOS tile according to claim 14 wherein said plurality of pixels of said CMOS tile are internally configured into blocks, each block sharing common readout and control electronics thereby to allow for a readout rate of 30 fps or more.

17. An array of CMOS tiles for use in imaging wherein each tile is comprised of a plurality of pixels for receiving charges from a charge-providing source and each of said tiles has four side abuttability, each of said tiles is spaced one pixel apart from each of its nearest neighbor tiles and said plurality of pixels of said tiles are internally configured into blocks, each block sharing common readout and control electronics thereby to allow for a readout rate of 30 fps or more.

18. An array according to claim 17 wherein each of said CMOS tiles further includes at least one through-hole whereby a signal generated by the charges received by said tile pixels is transferred through said through-hole and brought to at least one analog-to-digital converter.

19. An array according to claim 18 wherein said at least one through-hole is sized to replace no more than a single pixel in said CMOS tile.

20. An array according to claim 17 wherein each of said pixels comprises at least one amplifier, at least one integrating capacitor and at least one storage capacitor for integrating and storing charge arriving from a charge-providing source.

21. An array according to claim 18, wherein each of said tiles further includes at least one over-the-tile-edge connection positioned in said spacing between said tiles, whereby a signal generated by the charges collected by said tile pixels is transferred through said connection to said at least one analog-to-digital converter.

22. A method for achieving high data readout rates in a two-dimensional imaging system, said method including the steps of:
providing a detector of the system with an array of CMOS tiles, each tile including a plurality of pixels; and
configuring the plurality of pixels into groups, each group sharing common readout and control electronics thereby to allow data readout at a rate of 30 fps or more.
